(19) United States
(12) Patent Application Publication
(10) Pub. No.: US 2025/0008801 A1
(43) Pub. Date: Jan. 2, 2025

(54) Display Panel and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Ling Shi, Beijing (CN); Yipeng Chen, Beijing (CN)

(21) Appl. No.: 18/689,583

(22) PCT Filed: Jan. 3, 2023
(86) PCT No.: PCT/CN2023/070091

§ 371 Date: Mar. 6, 2024

(51) Int. Cl. H10K 59/35; H10K 59/131; H10K 59/95

(52) U.S. Cl. CPC H10K 59/353; H10K 59/131; H10K 59/95

(57) ABSTRACT

A display panel includes a substrate, sub-pixels, data lines and a pixel defining layer. The data lines are divided into data line groups. Each data line group includes a first data line, a second data line and a third data line sequentially arranged in a first direction. Adjacent second and third data lines are substantially symmetrical about an axis. The second data line and the third data line each include first straight segments and first bending segments alternately connected. For first bending segments of the adjacent second and third data lines, each is bent in a direction away from another. The pixel defining layer is provided therein with photosensitive openings. An orthogonal projection, on the substrate, of a photosensitive opening is located between orthogonal projections, on the substrate, of adjacent first bending segments of a second data line and a third data line.

### CROSS-REFERENCE TO RELATED APPLICATION

This application is the United States national phase of International Patent Application No. PCT/CN2023/070091, filed Jan. 3, 2023, the disclosure of which is hereby herein by reference in its entirety.

### BACKGROUND OF THE INVENTION

### Field of the Invention

The present disclosure relates to the field of display technologies, and in particular, to a display panel and a display apparatus.

### Description of Related Art

With the rapid development of display technologies, display apparatuses have gradually come throughout people's lives. Organic light-emitting diodes (OLEDs) are widely used in smart products such as mobile phones, televisions, notebook computers, etc. due to their advantages of self-illumination, low power consumption, wide viewing angle, fast response speed, high contrast, and flexible display.

### SUMMARY OF THE INVENTION

In an aspect, a display panel is provided. The display panel includes a substrate, a plurality of sub-pixels, a plurality of data lines and a pixel defining layer. The plurality of sub-pixels are disposed on the substrate. The plurality of sub-pixels include a plurality of red sub-pixels, a plurality of green sub-pixels and a plurality of blue sub-pixels. The plurality of data lines are disposed on the substrate. The plurality of data lines are divided into a plurality of data line groups, and each data line group includes a first data line, a second data line and a second data line arranged sequentially in a first direction. The first data line is electrically connected to red sub-pixels, the second data line is electrically connected to green sub-pixels, and the third data line is electrically connected to blue sub-pixels.

A second data line and a third data line that are adjacent are substantially symmetrical about a first axis, the first axis extending in a second direction, the second direction being substantially perpendicular to the first direction; the second data line and the third data line each include first straight segments and first bending segments that are alternately connected; and for a first bending segment of the second data line and a first bending segment of the third data line that are adjacent, each is bent in a direction away from another.

The pixel defining layer is disposed on a side of the plurality of data lines away from the substrate. The pixel defining layer is provided therein with a plurality of photosensitive openings, and an orthogonal projection, on the substrate, of a photosensitive opening is located between orthogonal projections, on the substrate, of adjacent first bending segments of a second data line and a third data line.

In some embodiments, the display panel further includes a plurality of power lines, and the plurality of power lines are disposed on the substrate. The plurality of power lines are divided into a plurality of power line groups, and each power line group includes a first power line, a second power line and a third power line arranged sequentially in the first direction; the first power line is electrically connected to red sub-pixels, the second power line is electrically connected to green sub-pixels, and the third power line is electrically connected to blue sub-pixels.

A first power line and a second power line belonging to the same power line group are located between a first data line and a second data line belonging to the same data line group, and the third power line is located between a third data line and a first data line that belong to different data line groups and are adjacent.

In some embodiments, the pixel defining layer is provided therein with first pixel openings, second pixel openings and third pixel openings. A red sub-pixel covers a first pixel opening, a green sub-pixel covers a second pixel opening, and a blue sub-pixel covers a third pixel opening; and orthogonal projections, on the substrate, of the first pixel opening and the second pixel opening are located within an orthogonal projection, on the substrate, of the first power line.

In some embodiments, the first power line includes a main body portion, a first extension portion and a second extension portion; the first extension portion and the second extension portion are located on a side of the main body portion close to an adjacent first data line, and are connected to the main body portion; an orthogonal projection of the first pixel opening on the substrate partially overlaps with an orthogonal projection of the first extension portion on the substrate; and an orthogonal projection of the second pixel opening on the substrate partially overlaps with an orthogonal projection of the second extension portion on the substrate.

In some embodiments, the first data line includes a plurality of data sub-segments that are repeated, and each data sub-segment includes a second straight segment, a second bending segment, a third straight segment and a third bending segment that are sequentially connected; the second straight segment and the third straight segment extend substantially in the second direction; the second bending segment and the third bending segment are each bent in a direction close to an adjacent third power line; and a first extension portion of an adjacent first power line is located on a side of the second bending segment away from the adjacent third power line, and a second extension portion of the adjacent first power line is located on a side of the third bending segment away from the adjacent third power line.

In some embodiments, the plurality of data lines each include first lapping portions; a first lapping portion of the first data line is disposed on a side of the second straight segment close to the adjacent first power line, and is connected to the second straight segment; and/or, a first lapping portion of the second data line is disposed on at least one side of a first bending segment of the second data line, and is connected to the first bending segment of the second data line; and/or, a first lapping portion of the third data line is disposed on at least one side of a first bending segment of the third data line, and is connected to the first bending segment of the third data line.

In some embodiments, a first power line and a second power line that are adjacent are arranged separately, and the first power line and the second power line that are adjacent have a gap therebetween; or, the first power line and the second power line that are adjacent are of an integrated structure.

In some embodiments, a blue pixel is disposed between two adjacent photosensitive openings in the second direction.

In some embodiments, the pixel defining layer is provided therein with first pixel openings, second pixel openings and third pixel openings; and orthogonal projections, on the substrate, of a second data line and a third data line belonging to the same data line group and an orthogonal projection, on the substrate, of a third pixel opening overlap, and overlapping portions thereof are substantially symmetrical about the first axis.

In some embodiments, the display panel includes a plurality of power lines, and the plurality of power lines are divided into a plurality of power line groups. The orthogonal projection, on the substrate, of the third pixel opening and orthogonal projections, on the substrate, of a second power line and a third power line belonging to the same power line group partially overlap, and overlapping portions thereof are substantially symmetrical about the first axis.

In some embodiments, the orthogonal projection, on the substrate, of the third pixel opening is located between orthogonal projections, on the substrate, of two edges, which are far away from each other, of the second power line and the third power line belonging to the same power line group.

In some embodiments, the plurality of sub-pixels each include a pixel circuit, and pixel circuits of the green sub-pixels and pixel circuits of the blue sub-pixels are substantially symmetrical about the first axis.

In some embodiments, each first bending segment includes a first straight sub-segment, a second straight sub-segment and a third straight sub-segment that are sequentially connected; the first straight sub-segment and the third straight sub-segment are respectively connected to first straight segments on two sides of the first bending segment; an extending direction of the second straight sub-segment is substantially the same as an extending direction of a first straight segment connected to the second straight sub-segment; and the second straight sub-segment is farther away from the first axis compared with the first straight segment connected to the second straight sub-segment.

In some embodiments, the photosensitive opening includes a first straight edge, a first folded edge, a second straight edge and a second folded edge that are sequentially connected. The first folded edge includes three first straight sub-edges that are sequentially connected; the second folded edge includes three second straight sub-edges that are sequentially connected; the first folded edge is opposite to a first bending segment of an adjacent second data line; and the second folded edge is opposite to a first bending segment of an adjacent third data line.

The three first straight sub-edges of the first folded edge are in one-to-one correspondence with and respectively substantially parallel to a first straight sub-segment, a second straight sub-segment and a third straight sub-segment of the adjacent second data line; and the three second straight sub-edges of the second folded edge are in one-to-one correspondence with and respectively substantially parallel to a first straight sub-segment, a second straight sub-segment and a third straight sub-segment of the adjacent third data line.

In some embodiments, the plurality of red sub-pixels and the plurality of green sub-pixel arrays are arranged in an array with a plurality of rows and a plurality of columns, each row includes red sub-pixels or green sub-pixels arranged in the first direction, and each column includes red sub-pixels and green sub-pixels staggered in the second direction; and the plurality of blue sub-pixels are arranged an array with a plurality of rows and a plurality of columns, and one blue sub-pixel is disposed between each adjacent red sub-pixels and green sub-pixels that are arranged in two rows and two columns.

In some embodiments, the pixel defining layer is provided therein with first pixel openings, second pixel openings and third pixel openings; orthogonal projections, on the substrate, of the first pixel openings, the second pixel openings and the third pixel openings are substantially circular.

In some embodiments, the display panel includes a first semiconductor layer, a first gate conductive layer, a second gate conductive layer, a second semiconductor layer, a third gate conductive layer, a first source-drain conductive layer and a second source-drain conductive layer that are sequentially arranged in a direction perpendicular to the substrate and away from the substrate; the data lines are located in the second source-drain conductive layer; and in a case where the display panel further includes the power lines, the power lines are located in the second source-drain conductive layer.

In some embodiments, the pixel defining layer is provided therein with a plurality of pixel openings; and the display panel further includes a black matrix, the black matrix being disposed on a side of the pixel defining layer away from the substrate. The black matrix is provided therein with a plurality of first avoidance openings and a plurality of second avoidance openings. An orthogonal projection, on the substrate, of a single pixel opening is located within an orthogonal projection, on the substrate, of a single first avoidance opening; and an orthogonal projection, on the substrate, of a single photosensitive opening is located within an orthogonal projection, on the substrate, of a single second avoidance opening.

In some embodiments, the display panel further includes a plurality of filter patterns disposed on a side of the black matrix away from the substrate, and the orthogonal projection, on the substrate, of the single first avoidance opening is located within an orthogonal projection, on the substrate, of a single filter pattern.

In another aspect, a display apparatus is provided. The display apparatus includes the display panel as described in any of the above embodiments and a photosensitive device. The display panel has a photosensitive region, and the photosensitive device is disposed under the photosensitive region of the display panel.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a sectional view of a display apparatus, in accordance with some embodiments;

FIG. 3 is an exploded view of a display apparatus, in accordance with some embodiments;

FIG. 4 is a sectional view taken along the A-A′ line in FIG. 3;

FIG. 5 is a top view of a second source-drain conductive layer of a display panel, in accordance with some embodiments;

FIG. 6A is a top view of a structure where pixel openings and photosensitive openings are provided on the second source-drain conductive layer in FIG. 5;

FIG. 6B is a top view of a structure where first avoidance openings, second avoidance openings and filter patterns are provided on the structure in FIG. 6A;

FIG. 7 is an enlarged view of a photosensitive opening, in accordance with some embodiments;

FIG. 8 is a top view of a first semiconductor layer, in accordance with some embodiments;

FIG. 9 is a top view of a structure where a first gate conductive layer is provided on the structure in FIG. 8;

FIG. 10 is a top view of a structure where a second gate conductive layer is provided on the structure in FIG. 9;

FIG. 11 is a top view of a structure where a second semiconductor layer is provided on the structure in FIG. 10;

FIG. 12 is a top view of a structure where a third gate conductive layer is provided on the structure in FIG. 11;

FIG. 13 is a top view of a structure where a first source-drain conductive layer is provided on the structure in FIG. 12;

FIG. 14 is a top view of a structure where a second source-drain conductive layer is provided on the structure in FIG. 13; and

FIG. 15 is a top view of a structure where first electrodes, photosensitive openings and pixel openings are provided on the structure in FIG. 14.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating a number of indicated technical features. Thus, features defined with “first” and “second” may explicitly or implicitly include one or more of the features. In the description of the embodiments of the present disclosure, the term “multiple”, “a plurality of” or “the plurality of” means two or more unless otherwise specified.

In the description of some embodiments, the terms such as “coupled” and “connected” and their derivatives may be used. The term “connected” should be understood in a broad sense. For example, the term “connected” may represent a fixed connection, a detachable connection, or a one-piece connection, or may represent a direct connection, or may represent an indirect connection through an intermediate medium. For example, the term “coupled” indicates that two or more components are in direct physical or electrical contact with each other. The term “coupled” or “communicatively coupled” may also mean that two or more components are not in direct contact with each other but still cooperate or interact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes following three combinations: only A, only B, and a combination of A and B.

As used herein, the term “if” is, optionally, construed as “when” or “in a case where” or “in response to determining that” or “in response to detecting,” depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event].”

The use of the phrase “applicable to” or “configured to” herein means an open and inclusive expression, which does not exclude devices that are applicable to or configured to perform additional tasks or steps.

Additionally, the use of the phase “based on” is meant to be open and inclusive, since a process, step, calculation or other action that is “based on” one or more of the stated conditions or values may, in practice, be based on additional conditions or value beyond those stated.

The term such as “about,” “substantially,” and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°. The term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views that are schematic illustrations of idealized embodiments. In the accompanying drawings, thicknesses of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

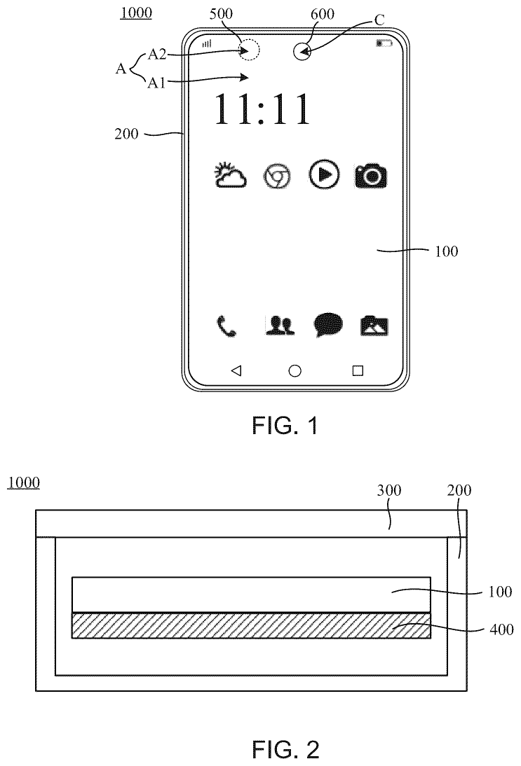

Referring to FIG. 1, some embodiments of the present disclosure provide a display apparatus 1000. The display apparatus 1000 may be any device that displays an image whether in motion (e.g., a video) or stationary (e.g., a still image), and whether textual or graphical.

For example, the display apparatus 1000 may be any product or component having a display function, such as a television, a notebook computer, a tablet computer, a mobile phone, a personal digital assistant (PDA), a navigator, a wearable device, an augmented reality (AR) device, a virtual reality (VR) device, etc.

In some embodiments, referring to FIG. 1, the display apparatus 1000 includes a display panel 100.

For example, as shown in FIGS. 1 and 2, the display apparatus 1000 may further include a housing 200, a cover plate 300, a circuit board 400, a photosensitive device 500, a camera 600 and other electronic accessories.

As shown in FIG. 2, a longitudinal section of the housing 200 is, for example, U-shaped; the display panel 100 and the circuit board 200 are disposed in the housing 200; and the cover plate 300 is disposed on an opening of the housing 200.

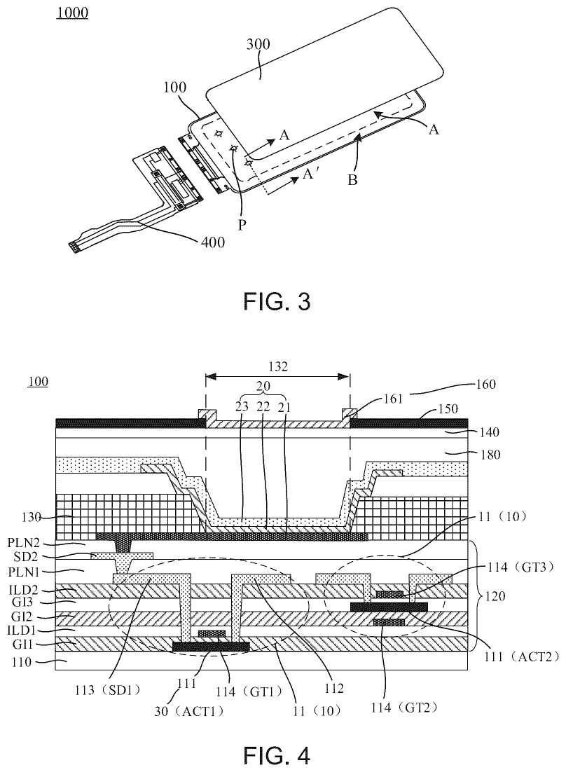

As shown in FIGS. 2 and 3, the circuit board 400 may be bonded to the display panel 100 at an end of the display panel 100 and bent to a back side of the display panel 100, which facilitates a narrow bezel design of the display apparatus 1000.

As shown in FIGS. 1 and 3, for example, the photosensitive device 500 and the camera 600 may be integrated on a lower side of the display panel 100 to increase a screen-to-body ratio. The photosensitive device 500 includes at least one of an infrared sensor, a distance sensor, a fingerprint recognition module and a brightness adjustment module.

A type of the display panel 100 varies, which may be set according to actual needs.

For example, the display panel 100 may be an organic light-emitting diode (OLED) display panel, a quantum dot light-emitting diode (QLED) display panel, or the like, which is not specifically limited in the embodiments of the present disclosure.

Some embodiments of the present disclosure are schematically described below by considering an example in which the display panel 100 is an OLED display panel.

In some embodiments, referring to FIG. 3, the display panel 100 has a display region A and a peripheral region B disposed on at least one side of the display region A. FIG. 3 illustrates an example in which the peripheral region B is disposed around the display region A.

The display region A is a region where images are displayed, and is configured to be provided therein with a plurality of sub-pixels P. The peripheral region B is a region where no image is displayed, and is configured to be provided therein with display driving circuits, such as a gate driving circuit and a source driving circuit.

In some examples, referring to FIG. 1, the display region A may include a main display region A1 and a photosensitive region A2, and the main display region A1 surrounds the photosensitive region A2. The photosensitive device 500 is located under the photosensitive region A2 of the display panel 100.

Here, referring to FIGS. 1 and 3, the photosensitive region A2 may be located at the top of the display region A, that is, a portion of the display region A that is far away from a bonding portion of the display panel 100; or, the photosensitive region A2 may be located at other locations in the display region A. Details will not be provided here in the embodiments of the present disclosure.

It should be noted that a shape of the photosensitive region A2 may be any of a circle, a polygon, and an irregular pattern, and details will not be provided here in the embodiments of the present disclosure.

In some embodiments, referring to FIG. 1, the display panel 100 may further have a camera region C, and the camera 600 is located on a lower side of the camera region C of the display panel 100.

The display region A may, for example, surround the camera region C; and the camera region C may be located at the top of the display region A, that is, a portion of the display region A that is far away from a bonding portion of the display panel 100; or the camera region C may be located at other locations in the display region A. Details will not be provided here in the embodiments of this disclosure.

In the related art, a region (the photosensitive region) where the photosensitive device is located has a low comprehensive transmittance, the photosensitive device receives less external ambient light, and the photosensitive sensitivity is low, which adversely affects the automatic brightness adjustment function and touch function of the display panel.

Herein, the comprehensive transmittance refers to a product of the transmittance of the display panel 100 in the photosensitive region A2 and the aperture ratio of the photosensitive opening in the photosensitive region A2.

In light of this, referring to FIGS. 3, 4 and 5, some embodiments of the present disclosure provide a display panel 100 including a substrate 110, a plurality of sub-pixels P, a plurality of data lines 120 and a pixel defining layer 130.

Referring to FIG. 4, a type of the substrate 110 varies, which may be set according to actual needs.

For example, the substrate 110 may be a rigid substrate. For example, the rigid substrate may be a glass substrate or a polymethyl methacrylate (PMMA) substrate.

For example, the substrate 110 may be a flexible substrate. For example, the flexible substrate may be a polyethylene terephthalate (PET) substrate, a polyethylene naphthalate (PEN) substrate, or a polyimide (PI) substrate.

Referring to FIGS. 3 to 4, the plurality of sub-pixels 2 are disposed on the substrate 110, and are located in the display region A.

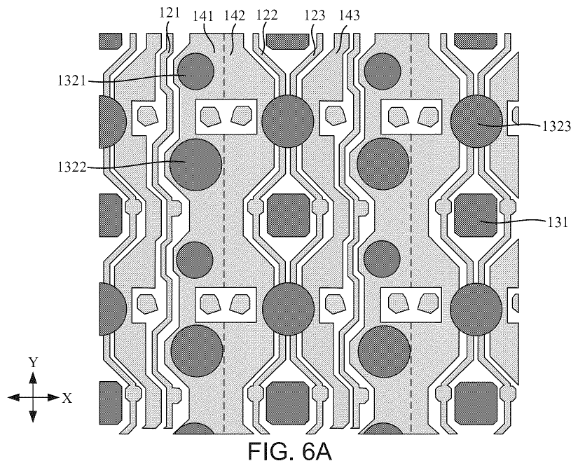

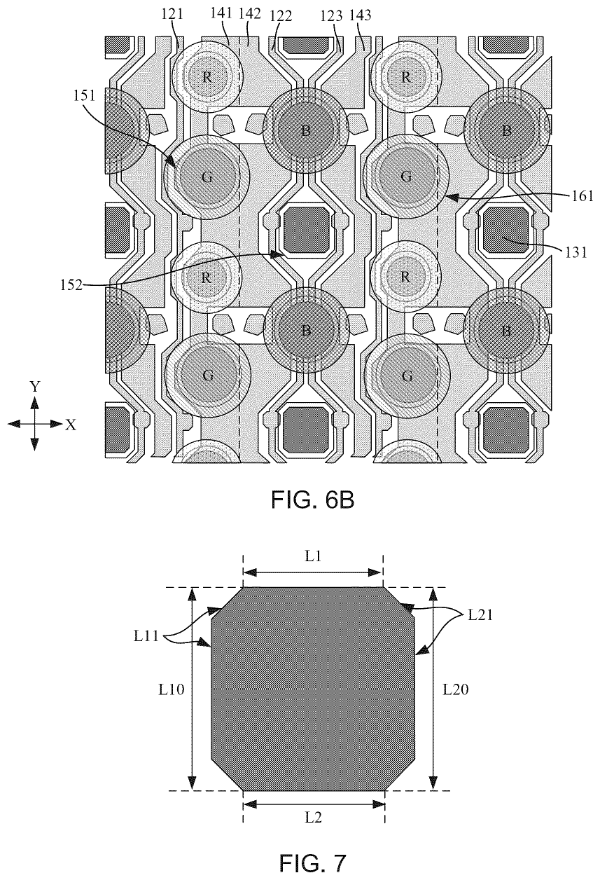

The plurality of sub-pixel regions P include sub-pixels emitting light of various colors. For example, as shown in FIGS. 3 and 6B, the plurality of sub-pixels P include a plurality of red sub-pixels R emitting light of red, a plurality of green sub-pixels G emitting light of green, and a plurality of blue sub-pixels B emitting light of blue.

Here, the arrangement manners of the red sub-pixels R, the green sub-pixels G and the blue sub-pixels B are not unique.

For example, as shown in FIG. 6B, the plurality of red sub-pixels R and the plurality of green sub-pixels G are arranged in an array with multiple rows and multiple columns, and each row includes multiple red sub-pixels R or multiple green sub-pixels G arranged in a first direction X, and each column includes multiple red sub-pixels R and multiple green sub-pixels G staggered in a second direction Y.

It should be noted that the first direction is a row direction in which the plurality of red sub-pixels R or the plurality of green sub-pixels G are arranged, and the second direction Y is a column direction in which the plurality of red sub-pixels R and the plurality of green sub-pixels G are arranged.

On this basis, the plurality of blue sub-pixels B are arranged in an array with multiple rows and multiple columns, and there is one blue sub-pixel B between each adjacent red sub-pixels R and green sub-pixels G that are arranged in two rows and two columns.

Referring to FIGS. 3 and 4, each sub-pixel P includes a pixel circuit 10 and a light-emitting device 20 that are disposed on the substrate 110.

As shown in FIG. 4, the pixel circuit 10 includes a plurality of thin film transistors 11. The thin film transistor 11 includes an active layer 111, a source 112, a drain 113 and a gate 114. The source 112 and the drain 113 are both in contact with the active layer 111.

It should be noted that the source 112 and the drain 113 can be interchanged. That is, in FIG. 4, 112 represents the drain, and 113 represents the source.

As shown in FIG. 4, the light-emitting device 20 includes a first electrode 21, a light-emitting functional layer 22, and a second electrode 23; for example, the first electrode 21 is electrically connected to a source 112 or drain 113 of a thin film transistor 11, serving as a driving transistor, among the plurality of thin film transistors 11; in FIG. 4, the first electrode 21 is electrically connected to the drain 113 of the thin film transistor 11.

It should be noted that the first electrode 21 is the anode of the light-emitting device 20, and the second electrode 23 is the cathode of the light-emitting device 20; or, the first electrode 21 is the cathode of the light-emitting device 20, and the second electrode 23 is the anode of the light-emitting device 20. The embodiments of the present disclosure are described below by taking an example where the first electrode 21 is the anode of the light-emitting device 20 and the second electrode 23 is the cathode of the light-emitting device 20.

The light-emitting functional layer 22 may include only a light-emitting layer; or the light-emitting functional layer 22 may include the light-emitting layer, and further include at least one of an electron transport layer (ETL), an electron injection layer (EIL), a hole transport layer (HTL) and a hole injection layer (HIL).

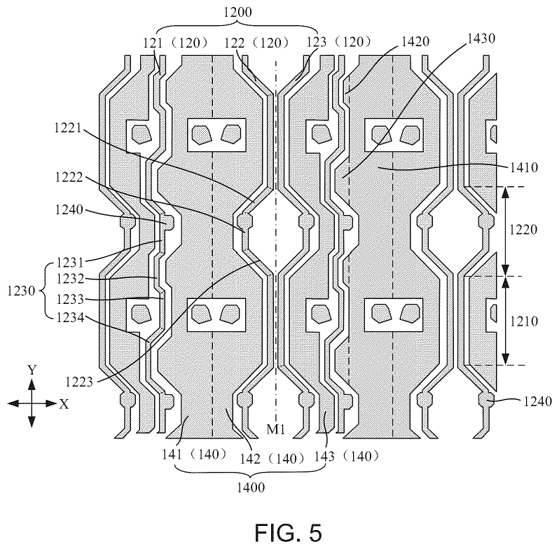

Referring to FIGS. 4 and 5, the data lines 120 are disposed on the substrate 110.

As shown in FIGS. 5 and 6B, the data lines 120 extend substantially in the second direction Y. All the data lines 120 are divided into a plurality of data line groups 1200, and each data line group 1200 includes a first data line 121, a second data line 122 and a third data line 123 sequentially arranged in the first direction X. The first data line 121 is electrically connected to red sub-pixels R, the second data line 122 is electrically connected to green sub-pixels G, and the third data line 123 is electrically connected to blue sub-pixels B.

It should be noted that the data line 120 includes lapping portions (which may also be referred to as first lapping portions herein) 1240, and the data line 120 is electrically connected to a pixel circuit 10 (referring to FIG. 4) of a sub-pixel P (referring to FIG. 3) through a first lapping portion 1240. As for details of the positions of the first lapping portions 1240, reference can be made to the following description.

On this basis, referring to FIG. 5, adjacent second data line 122 and third data line 123 are substantially symmetrical about an axis (which is also referred to as a first axis herein) M1. The second data line 122 and the third data line 123 each include first straight segments 1210 and first bending segments 1220 that are alternately connected; and for the first bending segment 1220 of the second data line 122 and the first bending segment 1220 of the third data line 123 that are adjacent, each is bent in a direction away from another, resulting in avoidance.

It should be noted that the first axis M1 extends in the second direction Y, and the second direction Y is substantially perpendicular to the first direction X.

The first bending segment 1220 may be substantially an arc-shaped line segment, or may be a line segment composed of multiple straight line segments that are connected.

For example, as shown in FIG. 5, the first bending segment 1220 includes a first straight sub-segment 1221, a second straight sub-segment 1222 and a third straight sub-segment 1223 that are sequentially connected. The first straight sub-segment 1221 and the third straight sub-segment 1223 are respectively connected to first straight segments 1210 on two sides of the first bending segment 1220. An extending direction of the second straight sub-segment 1222 is substantially the same as an extending direction of the first straight segment 1210, and the second straight sub-segment 1222 is farther away from the first axis M1 compared with the first straight segment 1210.

Here, referring to FIG. 5, a first lapping portion 1240 of the second data line 122 may be disposed on at least one side of a first bending segment 1220 of the second data line 122, and is connected to the first bending segment 1220 of the second data line 122.

For example, as shown in FIG. 5, first lapping portions 1240 of the second data line 122 are located on two opposite sides, in the first direction X, of the first bending segment 1220 of the second data line 122, and a part of the first bending segment 1220 of the second data line 122 is used as a part of the first lapping portion 1240.

In addition, referring to FIG. 5, a first lapping portion 1240 of the third data line 123 may be disposed on at least one side of a first bending segment 1220 of the third data line 123, and is connected to the first bending segment 1220 of the third data line 123.

For example, as shown in FIG. 5, first lapping portions 1240 of the third data line 123 are located on two opposite sides, in the first direction X, of the first bending segment 1220 of the third data line 123, and a part of the first bending segment 1220 of the third data line 123 is used as a part of the first lapping portion 1240.

Referring to FIG. 4, the pixel defining layer 130 is disposed on a side of the data lines 120 away from the substrate 110.

Referring to FIGS. 4, 5 and 6A, the pixel defining layer 130 is provided therein with a plurality of photosensitive openings 131. An orthogonal projection of the photosensitive opening 131 on the substrate 110 is located between orthogonal projections, on the substrate 110, of the first bending segment 1220 of the second data line 122 and the first bending segment 1220 of the third data line 123 that are adjacent.

It can be seen from the above that in the display panel 100 provided in the embodiments of the present disclosure, the photosensitive opening 131 is located between the first bending segment 1220 of the second data line 122 and the first bending segment 1220 of the third data line 123 that are adjacent; and for the first bending segment 1220 of the second data line 122 and the first bending segment 1220 of the third data line 123 that are adjacent, each is bent in a direction away from another, resulting in avoidance. In this way, it may be possible to increase an area of the photosensitive opening 131, and in turn increase the aperture ratio of the photosensitive opening 131, improve the comprehensive transmittance of the photosensitive region A2, and improve the photo-sensitivity of the photosensitive device 500.

Referring to FIGS. 6A, 7 and 15, the photosensitive opening 131 includes a first straight edge L1, a first folded edge L10, a second straight edge L2 and a second folded edge L20 that are sequentially connected.

As shown in FIGS. 5, 6A and 7, the first folded edge L10 is opposite to an adjacent first bending segment 1220 of a second data line 122, and the second folded edge L20 is opposite to an adjacent first bending segment 1220 of a third data line 123. On this basis, as shown in FIGS. 5, 7 and 15, the first folded edge L10 may include, for example, three first straight sub-edges L11 sequentially connected. The three first straight sub-edges L11 in the first folded edge L10 are in one-to-one correspondence with and respectively substantially parallel to a first straight sub-segment 1221, a second straight sub-segment 1222 and a third straight sub-segment 1223 of the second data line 122.

In addition, as shown in FIGS. 5, 7 and 15, the second folded edge L20 may include, for example, three second straight sub-edges L21 sequentially connected. The three second straight sub-edges L21 in the second folded edge L20 are in one-to-one correspondence with and respectively substantially parallel to a first straight sub-segment 1221, a second straight sub-segment 1222 and a third straight sub-segment 1223 of the third data line 123.

In this way, a distance between the photosensitive opening 131 and the first bending segments 1220 on two sides of the photosensitive opening 131 can be set to a process limit value, thereby increasing the area of the photosensitive opening 131 and improving the comprehensive transmittance of the photosensitive region A2.

For example, referring to FIGS. 5 and 6A, a minimum distance between a boundary of the photosensitive opening 131 and the first bending segments 1220 on the two sides is greater than or equal to 1 μm, so that the pixel defining layer 130 can cover the data lines 120 to avoid light leakage.

For example, as shown in FIGS. 5 and 6A, a distance between the boundary of the photosensitive opening 131 and the first bending segments 1220 on the two sides is in a range of 1 μm to 2 μm, inclusive. Therefore, the light leakage may be effectively avoided, and the area of the photosensitive opening 131 may be designed to be large.

In some embodiments, referring to FIGS. 4 and 5, the display panel 100 further includes a plurality of power lines 140.

As shown in FIGS. 4, 5 and 6B, the power lines 140 are provided on the substrate 110. All the power supply lines 140 are divided into a plurality of power line groups 1400. Each power line group 1400 includes a first power line 141, a second power line 142, and a third power line 143 sequentially arranged in the first direction X. The first power line 141 is electrically connected to red sub-pixels R, the second power line 142 is electrically connected to green sub-pixels G, and the third power line 143 is electrically connected to blue sub-pixels B.

Referring to FIG. 5, a first power line 141 and a second power line 142 belonging to the same power line group 1400 are located between a first data line 121 and a second data line 122 belonging to the same data line group 1200. A third power line 143 is located between a third data line 123 and a first data line 121 which belong to different data line groups 1200 and are adjacent. In this way, the circuit arrangement is more regular and compact, which facilitates the manufacturing with low production cost.

In some examples, adjacent first power line 141 and second power line 142 are arranged separately from each other, and there is a gap between the adjacent first power line 141 and second power line 142. In this way, it may be possible to reduce interference between different pixel circuits 10.

In some other examples, the adjacent first power line 141 and second power line 142 are of an integrated structure. In this way, it is conducive to increasing the section area of the power line 140, reducing the resistance, and reducing the impedance.

It should be understood that, referring to FIGS. 3 and 4, the pixel defining layer 130 is also provided therein with a plurality of pixel openings 132, one pixel opening 132 corresponds to one sub-pixel P, and a light-emitting device 20 of a single sub-pixel P is arranged in a single pixel opening 132.

For example, as shown in FIGS. 4, 6A and 6B, the plurality of pixel openings 132 include a first pixel opening 1321, a second pixel opening 1322 and a third pixel opening 1323. The red sub-pixel R covers the first pixel opening 1321, the green sub-pixel G covers the second pixel opening 1322, and the blue sub-pixel B covers the third pixel opening 1323.

That is, the light-emitting device 20 of the red sub-pixel R is located in the first pixel opening 1321, the light-emitting device 20 of the green sub-pixel G is located in the second pixel opening 1322, and the light-emitting device 20 of the blue sub-pixel B is located in the third pixel opening 1323.

An orthogonal projection, on the substrate 110, of the first pixel opening 1321 is located in an orthogonal projection, on the substrate 110, of the first power line 141.

For example, as shown in FIG. 5, the first power line 141 includes a main body portion 1410 and a first extension portion 1420. The first extension portion 1420 is located on a side of the main body portion 1410 close to an adjacent first data line 121, and is connected to the main body portion 1410.

On this basis, as shown in FIGS. 5 and 6A, the orthogonal projection, on the substrate 110, of the first pixel opening 1321 partially overlaps with an orthogonal projection, on the substrate 110, of the first extension portion 1420.

That is to say, a portion of the orthogonal projection, on the substrate 110, of the first pixel opening 1321 beyond an orthogonal projection, on the substrate 110, of the main body portion 1410 is located in the orthogonal projection, on the substrate 110, of the first extension portion 1420, so that the orthogonal projection of the first pixel opening 1321 on the substrate 110 is located in the orthogonal projection of the first power line 141 on the substrate 110.

In this case, under the first electrode 21 of the light-emitting device 20 of the red sub-pixel R (on a side thereof close to the substrate 110), there is a first power line 141 for support. Thus, the flatness of the first electrode 21 of the light-emitting device 20 of the red sub-pixel R is improved, and the direction deviation of light emitted by the light-emitting device 20 of the red sub-pixel R is reduced. As a result, the display brightness of the display panel 100 is more uniform, the problems of color separation and color cast in the display panel 100 are ameliorated, and the display effect is improved.

Moreover, circuits under the first electrodes 21 of the light-emitting devices 20 of all the red sub-pixels R are approximately arranged in the same way. That is, the first electrodes 21 of the light-emitting devices 20 of all the red sub-pixels R and the circuits thereunder create parasitic capacitances which are approximately the same, so that the display brightness of all the red sub-pixels R is more uniform, and the display effect is improved.

In addition, referring to FIGS. 5 and 6A, an orthogonal projection, on the substrate 110, of the second pixel opening 1322 is located in the orthogonal projection, on the substrate 110, of the first power line 141.

For example, as shown in FIGS. 5 and 6A, the first power line 141 includes a main body portion 1410 and a second extension portion 1430. The second extension portion 1430 is located on a side of the main body portion 1410 close to an adjacent first data line 121, and is connected to the main body portion 1410.

On this basis, an orthogonal projection of the second pixel opening 1322 on the first substrate 110 partially overlaps with an orthogonal projection of the second extension portion 1430 on the substrate 110.

That is to say, a portion of the orthogonal projection, on the substrate 110, of the second pixel opening 1322 beyond an orthogonal projection, on the substrate 110, of the main body portion 1410 is located in the orthogonal projection, on the substrate 110, of the second extension portion 1430, so that the orthogonal projection of the second pixel opening 1322 on the substrate 110 is located in the orthogonal projection of the first power line 141 on the substrate 110.

In this case, under the first electrode 21 of the light-emitting device 20 of the green sub-pixel G (on a side thereof close to the substrate 110), there is a first power line 141 for support. Thus, the flatness of the first electrode 21 of the light-emitting device 20 of the green sub-pixel G is improved, and the direction deviation of light emitted by the light-emitting device 20 of the green sub-pixel G is reduced. As a result, the display brightness of the display panel 100 is more uniform, the problems of color separation and color cast in the display panel 100 are ameliorated, and the display effect is improved.

Moreover, circuits under the first electrodes 21 of the light-emitting devices 20 of all the green sub-pixels G are approximately arranged in the same way. That is, the first electrodes 21 of the light-emitting devices 20 of all the green sub-pixels G and the circuits thereunder create parasitic capacitances which are approximately the same, so that the display brightness of all the green sub-pixels G is more uniform, and the display effect is improved.

In some examples, as shown in FIG. 6A, an area of the first pixel opening 1321 is less than an area of the second pixel opening 1322.

In this case, compared with the second pixel opening 1322, the portion of the orthogonal projection, on the substrate 110, of the first pixel opening 1321 beyond the orthogonal projection, on the substrate 110, of the main body portion 1410 is smaller. Therefore, an area of the first extension portion 1420 may be, for example, less than an area of the second extension portion 1430, so as to reduce the arrangement space of the first power lines 141 to make the circuit arrangement more compact.

In some embodiments, referring to FIGS. 6A and 6B, the blue sub-pixel B is disposed between two adjacent photosensitive openings 131 in the second direction Y.

On this basis, orthogonal projections, on the substrate 110, of the second data line 122 and the third data line 123 belonging to the same data line group 1200 overlap with an orthogonal projection, on the substrate 110, of the third pixel opening 1323, and overlapping portions are substantially symmetrical about the first axis M1.

For example, referring to FIGS. 5 and 6A, orthogonal projections, on the substrate 110, of the first straight segments 1210 of the second data line 122 and the third data line 123 belonging to the same data line group 1200 both overlap with the orthogonal projection, on the substrate 110, of the third pixel opening 1323, and overlapping portions are substantially symmetrical about the first axis M1.

In this case, the second data line 122 and the third data line 123 may balance heights of two sides, in the first direction X, of the first electrode 21 of the light-emitting device 20 of the blue sub-pixel B, so that heights, at positions symmetrical about the first axis M1, of the first electrode 21 of the light-emitting device 20 of the blue sub-pixel B are approximately equal. Therefore, the flatness of the first electrode 21 of the light-emitting device 20 of the blue sub-pixel B is improved, and the direction deviation of light emitted by the light-emitting device 20 of the blue sub-pixel B is reduced. As a result, the display brightness of the display panel 100 is more uniform, the problems of color separation and color cast in the display panel 100 are ameliorated, and the display effect is improved.

On this basis, referring to FIGS. 5 and 6A, an orthogonal projection of the third pixel opening 1323 on the substrate 110 partially overlaps with orthogonal projections, on the substrate 110, of the second power line 142 and the third power line 143 belonging to the same power line group 1400, and overlapping portions are substantially symmetrical about the first axis M1.

In this case, the second power supply line 142 and the third power supply line 143 may further balance the heights of the two sides, in the first direction X, of the first electrode 21 of the light emitting device 20 of the blue sub-pixel B, so that the heights, at the positions symmetrical about the first axis M1, of the first electrode 21 of the light-emitting device 20 of the blue sub-pixel B are further equalized, and the flatness of the first electrode 21 of the light-emitting device 20 of the blue sub-pixel B is further improved.

In addition, referring to FIGS. 5 and 6A, the orthogonal projection of the third pixel opening 1323 on the substrate 110 is located between orthogonal projections, on the substrate 110, of two edges, which are far away from each other, of the second power line 142 and the third power line 143 belonging to the same power line group 1400.

In this way, edges on the two sides, in the first direction X, of the first electrode 21 of the light-emitting device 20 of the blue sub-pixel B may be supported by the power supply lines 140. In this case, the heights of the two sides, in the first direction X, of the first electrode 21 of the light emitting device 20 of the blue sub-pixel B have good consistency and high flatness.

In some embodiments, referring to FIGS. 6B and 13, the pixel circuit 10 of the green sub-pixel G and the pixel circuit 10 of the blue sub-pixel B are substantially symmetrical about the first axis M1.

Based on this, overlapping regions of the orthogonal projection of the first electrode 21 of the light-emitting device 20 of the blue sub-pixel B on the substrate 110 and orthogonal projections of patterns included in pixel circuits 10 on the substrate 110 are also substantially symmetrical about the first axis M1. In this way, the heights of the two sides, in the first direction X, of the first electrode 21 of the light emitting device 20 of the blue sub-pixel B may be further balanced, and the flatness of the first electrode 21 of the light-emitting device 20 of the blue sub-pixel B is improved.

Moreover, circuits under the first electrodes 21 of the light-emitting devices 20 of all the blue sub-pixels B are approximately arranged in the same way. That is, the first electrodes 21 of the light-emitting devices 20 of all the blue sub-pixels B and the circuits thereunder create parasitic capacitances which are approximately the same, so that the display brightness of all the blue sub-pixels B is more uniform, and the display effect is improved.

In addition, shapes of the first pixel opening 1321, the second pixel opening 1322 and the third pixel opening 1323 are not unique.

For example, as shown in FIG. 6A, orthogonal projections of the first pixel opening 1321, the second pixel opening 1322 and the third pixel opening 1323 on the substrate 110 are each substantially circular. In this case, based on the arrangement manner of the sub-pixels P, since the pixel openings 132 are circular, it is conducive to increasing the distance between the adjacent third pixel openings 1323 in the second direction Y, and increasing the comprehensive transmittance of the photosensitive region A2 of the display panel 100.

It should be noted that a distance between adjacent third pixel openings 1323 in the second direction Y is approximately in a range of 50 μm to 65 μm, inclusive. For example, the distance between the adjacent third pixel openings 1323 in the second direction Y is approximately any one of 50 μm, 52.4 μm, 54 μm, 56.24 μm, 58.44 μm, 60 μm, and 65 μm.

In the case where the first power line 141 includes the main body portion 1410, the first extension portion 1420 and the second extension portion 1430, as shown in FIG. 5, the first data line 121 includes a plurality of data sub-segments 1230 that are repeated.

Each data sub-segment 1230 includes a second straight segment 1231, a second bending segment 1232, a third straight segment 1233 and a third bending segment 1234 that are sequentially connected. The second straight segment 1231 and the third straight segment 1233 substantially extend in the second direction Y. The second bending segment 1232 and the third bending segment 1234 are each bent in a direction close to an adjacent third power line 143.

On this basis, the first extension portion 1420 is located on a side of the second bending section 1232 away from the adjacent third power line 143, and the second extension portion 1430 is located on a side of the third bending segment 1234 away from the adjacent third power line 143. In this way, the circuit arrangement is more regular and compact.

In this case, the first lapping portion 1240 of the first data line 121 may, for example, be disposed on a side of the second straight segment 1231 close to an adjacent first power line 141, and is connected to the second straight segment 1231.

The pixel circuits 10 and circuit wirings will be schematically described below in conjunction with the film layer structure of the display panel 100.

For example, as shown in FIG. 4, the display panel 100 includes a first semiconductor layer ACT1, a first gate conductive layer GT1, a second gate conductive layer GT2, a second semiconductor layer ACT2, a third gate conductive layer GT3, a first source-drain conductive layer SD1 and a second source-drain conductive layer SD2 that are sequentially arranged in a direction perpendicular to the substrate 110 and away from the substrate 110.

It can be understood that, referring to FIG. 4, among the first semiconductor layer ACT1, the first gate conductive layer GT1, the second gate conductive layer GT2, the second semiconductor layer ACT2, the third gate conductive layer GT3, the first source-drain conductive layer SD1 and the second source-drain conductive layer SD2, each two adjacent layers have therebetween an insulating film layer, such as a first gate insulating layer Gl1, a first interlayer insulating layer ILD1, a second gate insulating layer GI2, a third gate insulating layer GI3, a second interlayer insulating layer ILD2, a first planarization layer PLN1 and a second planarization layer PLN2, which will not be specifically limited here in the embodiments of the present disclosure.

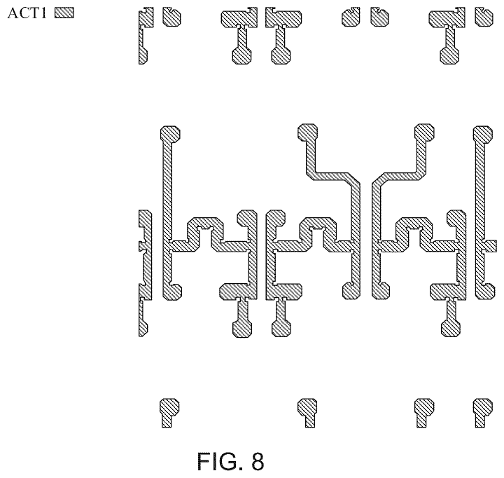

As shown in FIGS. 4, 8 and 11, the first semiconductor layer ACT1 includes active layers 111 of low-temperature polysilicon thin film transistors 11 in the pixel circuits 10. The second semiconductor layer ACT2 includes active layers 111 of oxide thin film transistors 11 in the pixel circuits 10.

It should be noted that a material of the first semiconductor layer ACT1 includes at least one of amorphous silicon, monocrystalline silicon or polycrystalline silicon. For example, the material of the first semiconductor layer ACT1 includes polysilicon. The embodiments of the present disclosure are not limited thereto. A material of the second semiconductor layer ACT2 includes metal oxide. For example, the material of the second semiconductor layer ACT2 includes indium gallium zinc oxide and/or indium gallium tin oxide.

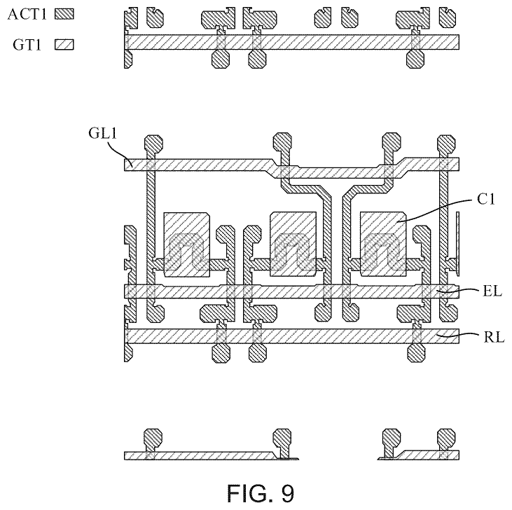

As shown in FIGS. 4 and 9, the first gate conductive layer GT1 includes first scan signal lines GL1, enable signal lines EL, reset signal lines RL and lower electrode plates C1 of storage capacitors. The first scan signal lines GL1, the enable signal lines EL, the reset signal lines RL and the first semiconductor layer ACT1 overlap to form a plurality of low-temperature polysilicon thin film transistors 11.

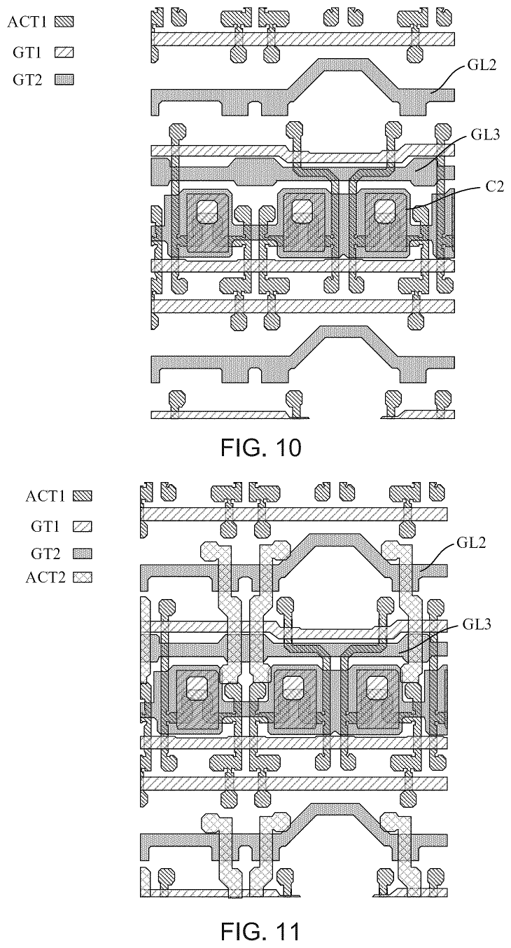

As shown in FIGS. 4 and 10, the second gate conductive layer GT2 includes second scan signal lines GL2, third scan signal lines GL3 and upper electrode plates C2 of the storage capacitors. The second scan signal lines GL2, the third scan signal lines GL3 and the second semiconductor layer ACT2 overlap to form a plurality of oxide thin film transistors 11.

It should be noted that the second scan signal lines GL2 and the third scan signal lines GL3 form bottom gates of the oxide thin film transistors 11.

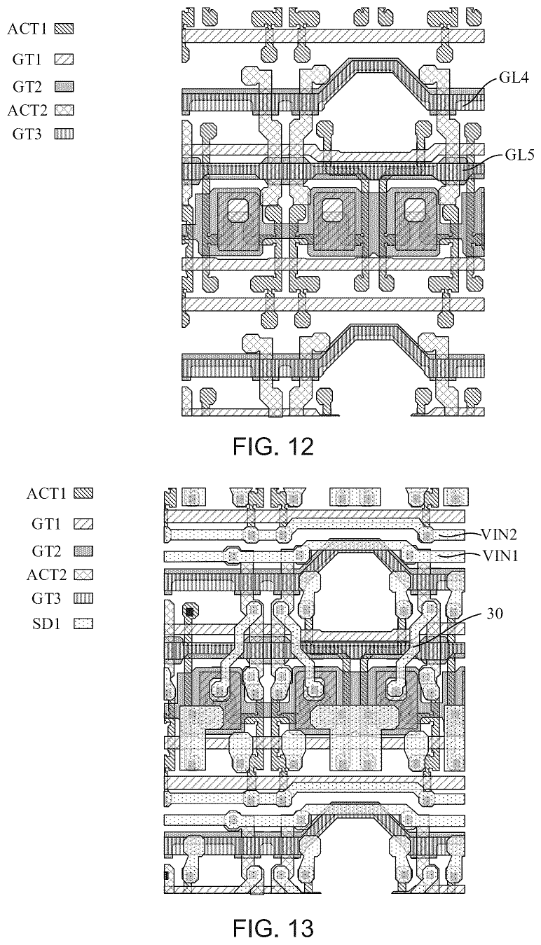

As shown in FIGS. 4 and 12, the third gate conductive layer GT3 includes fourth scan signal lines GL4 and fifth scan signal lines GL5. The fourth scan signal lines GL4, the fifth scan signal lines GL5 and the second semiconductor layer ACT2 overlap to form a plurality of oxide thin film transistors 11.

It should be noted that the fourth scan signal lines GL4 and the fifth scan signal lines GL5 form bottom gates of the oxide thin film transistors 11.

As shown in FIGS. 4 and 13, the first source-drain conductive layer SD1 includes transfer lines 30, first initialization signal lines VIN1 and second initialization signal lines VIN2. A plurality of thin film transistors 11 can be electrically connected through the transfer lines 30.

It should be noted that the first initialization signal lines VIN1 may, for example, reset control electrodes of the driving transistors. The second initialization signal lines 128 may, for example, reset the anodes of the light emitting devices 20 (referring to FIG. 4).

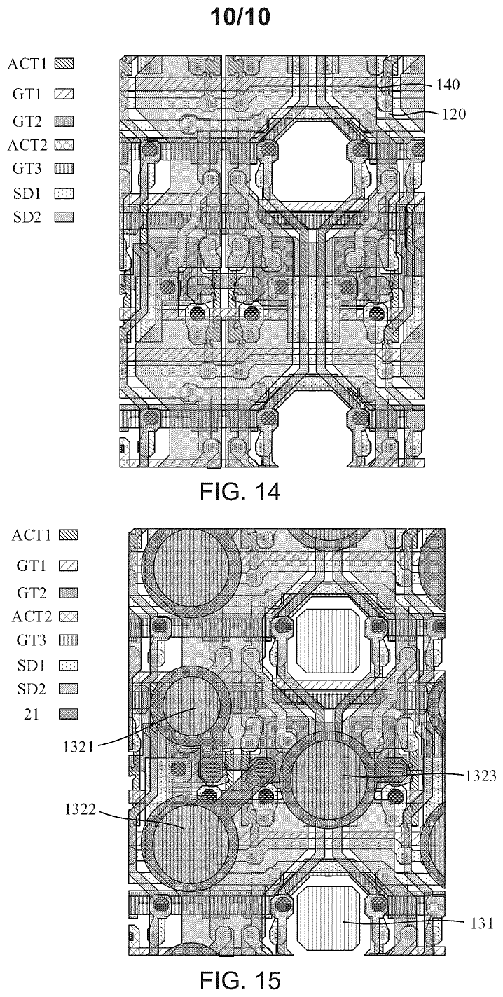

As shown in FIGS. 4 and 14, the second source-drain conductive layer SD2 includes the data lines 120 and the power lines 140. That is, the data lines 120 are located in the second source-drain conductive layer SD2, and the power lines 140 are located in the second source-drain conductive layer SD2.

In some embodiments, referring to FIG. 4, the display panel 100 further includes a black matrix 150, and the black matrix 150 is disposed on a side of the pixel defining layer 130 away from the substrate 110.

It should be noted that the black matrix 150 is used to separate light emitted by different sub-pixels P, and has the function of reducing reflected light generated after the external ambient light enters an interior of the display panel 100.

As shown in FIG. 6B, the black matrix 150 is provided therein with a plurality of first avoidance openings 151 and a plurality of second avoidance openings 152.

An orthogonal projection, on the substrate 110, of a single pixel opening 132 (referring to FIG. 4) is located within an orthogonal projection, on the substrate 110, of a single first avoidance opening 151 (referring to FIG. 4). An orthogonal projection, on the substrate 110, of a single photosensitive opening 131 (referring to FIG. 4) is located within an orthogonal projection, on the substrate 110, of a single second avoidance opening 151 (referring to FIG. 4).

Here, referring to FIG. 6B, for example, a shape of the first avoidance opening 151 may be substantially the same as the shape of the pixel opening 132. For example, a shape of the second avoidance opening 152 may be substantially the same as the shape of the photosensitive opening 131.

An average distance between a boundary of the orthogonal projection of the first avoidance opening 151 on the substrate 110 and a boundary of the orthogonal projection of the pixel opening 132 on the substrate 110 is in a range of 2 μm to 6 μm inclusive, which facilitates the design of the wide viewing angle of the display panel 100. For example, the average distance between the boundary of the orthogonal projection of the first avoidance opening 151 on the substrate 110 and the boundary of the orthogonal projection of the pixel opening 132 on the substrate 110 is any one of 2 μm, 4 μm, and 6 μm.

A distance between a boundary of the orthogonal projection of the second avoidance opening 152 on the substrate 110 and a boundary of the orthogonal projection of the photosensitive opening 131 on the substrate 110 is in a range of 0 μm to 3.2 μm inclusive, so that the second avoidance opening 152 does not block the photosensitive open 131. For example, the distance between the boundary of the orthogonal projection of the second avoidance opening 152 on the substrate 110 and the boundary of the orthogonal projection of the photosensitive opening 131 on the substrate 110 is any one of 0 μm, 0.2 μm, 1 μm, 1.9 μm, 3 μm, and 3.2 μm.

In some embodiments, referring to FIG. 4, the display panel 100 further includes a color filter 160, and the color filter 160 is disposed on the side of the pixel defining layer 130 away from the substrate 110. Here, in the case where the display panel 100 includes the black matrix 150, the color filter 160 is disposed on a side of the black matrix 150 away from the substrate 110.

It should be noted that the color filter 160 can filter out most wavelength bands of light in the external ambient light, thereby reducing the intensity of the external ambient light reflected on the display panel 100.

As shown in FIGS. 4 and 6B, the color filter 160 includes a plurality of filter patterns 161; an orthogonal projection of a single first avoidance opening 151 on the substrate 110 is located within an orthogonal projection of a single filter pattern 161 on the substrate 110; and an orthogonal projection of a single pixel opening 132 on the substrate 110 is located within an orthogonal projection of a single filter pattern 161 on the substrate 110.

A distance between a boundary of the orthogonal projection of the filter pattern 161 on the substrate 110 and the boundary of the orthogonal projection of the first avoidance opening 151 on the substrate 110 is greater than or equal to 4.5 μm, so that the filter pattern 161 and the black matrix 150 have a high adhesiveness, which reduces the risk of the filter pattern 161 falling off from the black matrix 150.

In addition, a distance between of the boundary of the orthogonal projection of the filter pattern 161 on the substrate 110 and the boundary of the orthogonal projection of the photosensitive opening 131 on the substrate 110 is greater than or equal to 0 μm. For example, the distance between of the boundary of the orthogonal projection of the filter pattern 161 on the substrate 110 and the boundary of the orthogonal projection of the photosensitive opening 131 on the substrate 110 is in a range of 0 μm to 1.8 μm, inclusive. For example, the distance between of the boundary of the orthogonal projection of the filter pattern 161 on the substrate 110 and the boundary of the orthogonal projection of the photosensitive opening 131 on the substrate 110 is any one of 0 μm, 0.4 μm, 0.8 μm, 0.9 μm, 1.4 μm, 1.6 μm, and 1.8 μm.

Here, referring to FIG. 6B, a shape of the filter pattern 161 may be substantially the same as the shape of the pixel opening 132, or may be different from the shape of the pixel opening 132. FIG. 6B illustrates that the shape of the filter pattern 161 and the shape of the pixel opening 132 are substantially the same.

It should be noted that a material of the filter pattern 161 includes an organic insulating material. For example, the material of the filter pattern 161 includes at least one of general-purpose polymers such as polymethyl methacrylate and polystyrene, polymer derivatives having a phenol group, acryl-based polymers, imide-based polymers, aryl ether-based polymers, amide-based polymers, fluorine-based polymers, p-xylene-based polymers, and vinyl alcohol-based polymers.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a substrate;
a plurality of sub-pixels disposed on the substrate, the plurality of sub-pixels including a plurality of red sub-pixels, a plurality of green sub-pixels and a plurality of blue sub-pixels;
a plurality of data lines disposed on the substrate, wherein the plurality of data lines are divided into a plurality of data line groups, and each data line group includes a first data line, a second data line and a second data line arranged sequentially in a first direction; the first data line is electrically connected to red sub-pixels of the plurality of red sub-pixels, the second data line is electrically connected to green sub-pixels of the plurality of green sub-pixels, and the third data line is electrically connected to blue sub-pixels of the plurality of blue sub-pixels; a second data line and a third data line that are adjacent are substantially symmetrical about an axis, the axis extending in a second direction, the second direction being substantially perpendicular to the first direction; the second data line and the third data line each include first straight segments and first bending segments that are alternately connected; and for a first bending segment of the second data line and a first bending segment of the third data line that are adjacent, each is bent in a direction away from another; and
a pixel defining layer disposed on a side of the plurality of data lines away from the substrate, wherein the pixel defining layer is provided therein with a plurality of photosensitive openings, and an orthogonal projection, on the substrate, of a photosensitive opening is located between orthogonal projections, on the substrate, of adjacent first bending segments of a second data line and a third data line.

2. The display panel according to claim 1, further comprising:
a plurality of power lines disposed on the substrate, wherein the plurality of power lines are divided into a plurality of power line groups, and each power line group includes a first power line, a second power line and a third power line arranged sequentially in the first direction; the first power line is electrically connected to red sub-pixels of the plurality of red sub-pixels, the second power line is electrically connected to green sub-pixels of the plurality of green sub-pixels, and the third power line is electrically connected to blue sub-pixels of the plurality of blue sub-pixels;
a first power line and a second power line belonging to the same power line group are located between a first data line and a second data line belonging to the same data line group, and the third power line is located between a third data line and a first data line that belong to different data line groups and are adjacent.

3. The display panel according to claim 2, wherein the pixel defining layer is provided therein with first pixel openings, second pixel openings and third pixel openings; and
a red sub-pixel of the plurality of red sub-pixels covers a first pixel opening, a green sub-pixel of the plurality of green sub-pixels covers a second pixel opening, and a blue sub-pixel of the plural of blue sub-pixels covers a third pixel opening; and orthogonal projections, on the substrate, of the first pixel opening and the second pixel opening are located within an orthogonal projection, on the substrate, of the first power line.

4. The display panel according to claim 3, wherein the first power line includes a main body portion, a first extension portion and a second extension portion; the first extension portion and the second extension portion are located on a side of the main body portion close to an adjacent first data line, and are connected to the main body portion;
an orthogonal projection of the first pixel opening on the substrate partially overlaps with an orthogonal projection of the first extension portion on the substrate; and an orthogonal projection of the second pixel opening on the substrate partially overlaps with an orthogonal projection of the second extension portion on the substrate.

5. The display panel according to claim 4, wherein the first data line includes a plurality of data sub-segments that are repeated, and each data sub-segment includes a second straight segment, a second bending segment, a third straight segment and a third bending segment that are sequentially connected;
the second straight segment and the third straight segment extend substantially in the second direction; the second bending segment and the third bending segment are each bent in a direction close to an adjacent third power line; and
a first extension portion of an adjacent first power line is located on a side of the second bending segment away from the adjacent third power line, and a second extension portion of the adjacent first power line is located on a side of the third bending segment away from the adjacent third power line.

6. The display panel according to claim 5, wherein the plurality of data lines each include lapping portions;
a lapping portion of the first data line is disposed on a side of the second straight segment close to the adjacent first power line, and is connected to the second straight segment;
and/or, a lapping portion of the second data line is disposed on at least one side of a first bending segment of the second data line, and is connected to the first bending segment of the second data line;
and/or, a lapping portion of the third data line is disposed on at least one side of a first bending segment of the third data line, and is connected to the first bending segment of the third data line.

7. The display panel according to claim 2, wherein a first power line and a second power line that are adjacent are arranged separately, and the first power line and the second power line that are adjacent have a gap therebetween; or, the first power line and the second power line that are adjacent are of an integrated structure.

8. The display panel according to claim 1, wherein a blue pixel of the plurality of blue pixel is disposed between two adjacent photosensitive openings in the second direction.

9. The display panel according to claim 8, wherein the pixel defining layer is provided therein with first pixel openings, second pixel openings and third pixel openings; and
orthogonal projections, on the substrate, of a second data line and a third data line belonging to the same data line group and an orthogonal projection, on the substrate, of a third pixel opening overlap, and overlapping portions thereof are substantially symmetrical about the axis.

10. The display substrate according to claim 9, further comprising a plurality of power lines, wherein the plurality of power lines are divided into a plurality of power line groups, and each power line group includes a first power line, a second power line and a third power line arranged sequentially in the first direction; and
the orthogonal projection, on the substrate, of the third pixel opening and orthogonal projections, on the substrate, of a second power line and a third power line belonging to the same power line group partially overlap, and overlapping portions thereof are substantially symmetrical about the axis.

11. The display panel according to claim 10, wherein the orthogonal projection, on the substrate, of the third pixel opening is located between orthogonal projections, on the substrate, of two edges, which are far away from each other, of the second power line and the third power line belonging to the same power line group.

12. The display panel according to claim 1, wherein the plurality of sub-pixels each include a pixel circuit, and pixel circuits of the green sub-pixels and pixel circuits of the blue sub-pixels are substantially symmetrical about the axis.

13. The display panel according to claim 1, wherein each first bending segment includes a first straight sub-segment, a second straight sub-segment and a third straight sub-segment that are sequentially connected; the first straight sub-segment and the third straight sub-segment are respectively connected to first straight segments on two sides of the first bending segment; an extending direction of the second straight sub-segment is substantially the same as an extending direction of a first straight segment connected to the second straight sub-segment; and the second straight sub-segment is farther away from the axis compared with the first straight segment connected to the second straight sub-segment.

14. The display panel according to claim 13, wherein the photosensitive opening includes a first straight edge, a first folded edge, a second straight edge and a second folded edge that are sequentially connected;
the first folded edge includes three first straight sub-edges that are sequentially connected; the second folded edge includes three second straight sub-edges that are sequentially connected; the first folded edge is opposite to a first bending segment of an adjacent second data line; and the second folded edge is opposite to a first bending segment of an adjacent third data line;
the three first straight sub-edges of the first folded edge are in one-to-one correspondence with and respectively substantially parallel to a first straight sub-segment, a second straight sub-segment and a third straight sub-segment of the adjacent second data line; and the three second straight sub-edges of the second folded edge are in one-to-one correspondence with and respectively substantially parallel to a first straight sub-segment, a second straight sub-segment and a third straight sub-segment of the adjacent third data line.

15. The display panel according to claim 1, wherein the plurality of red sub-pixels and the plurality of green sub-pixel arrays are arranged in an array with a plurality of rows and a plurality of columns, each row includes red sub-pixels or green sub-pixels arranged in the first direction, and each column includes red sub-pixels and green sub-pixels staggered in the second direction; and
the plurality of blue sub-pixels are arranged an array with a plurality of rows and a plurality of columns, and one blue sub-pixel is disposed between each adjacent red sub-pixels and green sub-pixels that are arranged in two rows and two columns.

16. The display panel according to claim 1, wherein the pixel defining layer is provided therein with first pixel openings, second pixel openings and third pixel openings; orthogonal projections, on the substrate, of the first pixel openings, the second pixel openings and the third pixel openings are substantially circular.

17. The display panel according to claim 1, wherein the display panel comprises a first semiconductor layer, a first gate conductive layer, a second gate conductive layer, a second semiconductor layer, a third gate conductive layer, a first source-drain conductive layer and a second source-drain conductive layer that are sequentially arranged in a direction perpendicular to the substrate and away from the substrate;
the plurality of data lines are located in the second source-drain conductive layer; and the display panel further comprises power lines located in the second source-drain conductive layer.

18. The display panel according to claim 1, wherein the pixel defining layer is provided therein with a plurality of pixel openings; and the display panel further comprises:
a black matrix disposed on a side of the pixel defining layer away from the substrate, wherein the black matrix is provided therein with a plurality of first avoidance openings and a plurality of second avoidance openings;
an orthogonal projection, on the substrate, of a single pixel opening is located within an orthogonal projection, on the substrate, of a single first avoidance opening; and an orthogonal projection, on the substrate, of a single photosensitive opening is located within an orthogonal projection, on the substrate, of a single second avoidance opening.

19. The display panel according to claim 18, further comprising a plurality of filter patterns disposed on a side of the black matrix away from the substrate, wherein the orthogonal projection, on the substrate, of the single first avoidance opening is located within an orthogonal projection, on the substrate, of a single filter pattern.

20. A display apparatus, comprising:
the display panel according to claim 1, the display panel having a photosensitive region; and
a photosensitive device disposed under the photosensitive region of the display panel.
